(19) United States
(12) Patent Application Publication
(10) Pub. No.: US 2008/0175530 A1
(43) Pub. Date: Jul. 24, 2008

(54) PHOTOELECTRONIC WIRED FLEXIBLE PRINTED CIRCUIT BOARD USING OPTICAL FIBER

(76) Inventors: Jeong-Hwan SONG, Seoul (KR); Yun-Kyung Oh, Seoul (KR); Jeong-Seok Lee, Anyang-si (KR); Yu-Dong Bae, Suwon-si (KR)

Correspondence Address: CHA & REITER, LLC, 210 ROUTE 4 EAST STE 103, PARAMUS, NJ, 07652, US

(21) Appl. No.: 12/014,827

(22) Filed: Jan. 16, 2008

(30) Foreign Application Priority Data
Jan. 19, 2007 (KR) 6171-2007

(51) Int. Cl. G02B 6/12; H01L 21/02; H01L 31/12

(52) U.S. Cl. 385/14; 438/31; 257/E21.002; 257/E31.095

(57) ABSTRACT

A flexible printed circuit board module includes a flexible printed circuit board having a conductive layer in an upper part of the flexible printed circuit board, an optical fiber disposed under the flexible printed circuit board, light propagating through an interior of the optical fiber and a supporting member supporting an optical fiber and having a first reflecting member reflecting incident light from the flexible printed circuit board so as to connect the light to the optical fiber.

### CLAIM OF PRIORITY

This application claims the benefit of the earlier filing date, pursuant to 35 USC 119, to that patent application entitled “Flexible Printed Circuit Board Having Photoelectronic Wiring Using Optical Fiber,” filed in the Korean Intellectual Property Office on Jan. 19, 2007 and assigned Serial No. 2007-6171, the contents of which are hereby incorporated by reference.

### BACKGROUND OF THE INVENTION

1. Field of the Invention

The present invention relates to a flexible printed circuit board module, and more particularly to a flexible printed circuit board module having a photoelectronic wiring.

2. Description of the Related Art

Conventional flexible PCB modules having a hybrid optical/electric wirings known in the art include a module having a structure, which includes a flexible PCB, a light source and an optical detector mounted on the flexible printed circuit board, and a planar lightwave circuit attached to a lower surface of the flexible PCB, which is equipped with a light transmission medium, i.e. a core. Light output from the light source passes through the flexible PCB, propagates through the interior of the core, passes through the flexible PCB again, and is input to the optical detector.

FIG. 1 is a view illustrating a flexible PCB module having a typical photoelectronic wiring. The flexible PCB module 100 includes a flexible PCB 110 having at least one light source 160 and at least one optical detector 170 mounted on an upper surface thereof and a planar lightwave circuit 180 attached to a lower surface of the flexible PCB 110 by adhesives 175.

The flexible PCB 110 includes a substrate 120, a conductive layer 130, and an upper cover layer 140. The conductive layer 130 is stacked on an upper surface of the substrate 120 and has a pattern for an electric wiring. Such a pattern-shape is formed by a typical photolithography process. The light source 160 and the optical detector 170 are mounted on the conductive layer 130 by using conductive solder balls 150. The light source 160, the optical detector 170, and the conductive layer 130 are electrically connected with each other through the solder balls 150. The light source 160 and the optical detector 170 are driven by the flexible PCB 110. At this time, a light emitting surface of the light source 160 and a light receiving surface of the optical detector 170 face an exposed upper surface of the substrate 120. The upper cover layer 140 has insulating properties and is stacked on an upper surface of the conductive layer 130 so as to cover the exposed upper surface of the conductive layer 130.

The planar lightwave circuit 180 includes a core 220 of polymer material, lower and upper clads 200 and 230, a lower cover layer 190, and the first and second reflective layers 210 and 215. The lower clad 200, the first and second reflective layers 210 and 215, the core 220, and the upper clad 230 are sequentially stacked, and the lower cover layer 190 is stacked on a lower surface of the lower clad 200. The core 220 is a light transmitting medium, and the lower and upper clads 200 and 230 have a reflective index lower than a reflective index of the core 220. Therefore, the lower and upper clads 200 and 230 confine light within the core 220. The lower cover layer 190 has insulating properties and is stacked on the lower surface of the lower clad 200 so as to cover an exposed lower surface of the lower clad 200. The first and second reflective layers 210 and 215 are laid in the interior of the planar lightwave circuit 10. The first reflective layer 210 is arranged along an optical axis (corresponding to the propagating direction of outputting light) of the light source 160, and a part of the first reflective layer 210 is slanted against the optical axis at a 45 degree angle. Light output from the light source 160 passes through the substrate 120 and the upper clad 230 and enters the first reflective layer 210. The first reflective layer 210 reflects incident light at a right angle so that the reflected light can propagate along the longitudinal direction of the core 220. The second reflective layer 215 is arranged along the optical axis (corresponding to a reference axis of the light receiving angle) of the optical detector 170, and a part of the second reflective layer 215 is slanted against the optical axis of the optical detector 170 at a 45 degree angle. In addition, a typical optical detector has a cone-shaped light receiving area, and an axis of symmetry of such light receiving area may be a reference axis of the light receiving angle. The second reflective layer 215 reflects light entered from the core 220 at a right angle so that the reflected light can pass through the upper clad 230 and the substrate 120 and enter the light receiving surface of the optical detector 170.

The flexible PCB module 100 having the photoelectronic wiring described above has problems as described below.

Firstly, the flexible PCB module 100 has a structure that the flexible PCB 110 and the planar lightwave circuit 180, which have areas equal to each other, are attached thereto. Therefore, delamination between layers is easily caused due to the planar lightwave circuit 180 having a low ductility. Particularly, the planar lightwave circuit 180 has a ductility lower than the ductility of the flexible PCB 110 and, thus, decreasing the total ductility of the flexible PCB module 100.

Secondly, the planar lightwave circuit 180, which mainly is composed of a polymer material, is used, resulting in low reliability and the manufacturing process is too complicated.

Thirdly, the reflective layers 210 and 215, of low degree of surface roughness, have to be formed in the interior of the planar lightwave circuit 180. Therefore, the manufacturing process is troublesome.

### SUMMARY OF THE INVENTION

Accordingly, the present invention provides a flexible printed circuit board having a photoelectronic wiring that can improve the ductility and minimize delamination between layers.

In accordance with an aspect of the present invention, there is provided a flexible printed circuit board module including a flexible printed circuit board having a conductive layer in an upper surface of the flexible printed circuit board, an optical fiber disposed under the flexible printed circuit board, light propagating through an interior of the optical fiber and a supporting member supporting an optical fiber and having a first reflecting member reflecting incident light from the flexible printed circuit board so as to connect the light to the optical fiber.

### BRIEF DESCRIPTION OF THE DRAWINGS

The above and other aspects, features and advantages of the present invention will be more apparent from the following detailed description taken in conjunction with the accompanying drawings, in which:

FIG. 1 is a view illustrating a flexible printed circuit substrate (PCB) module having a typical photoelectronic wiring;

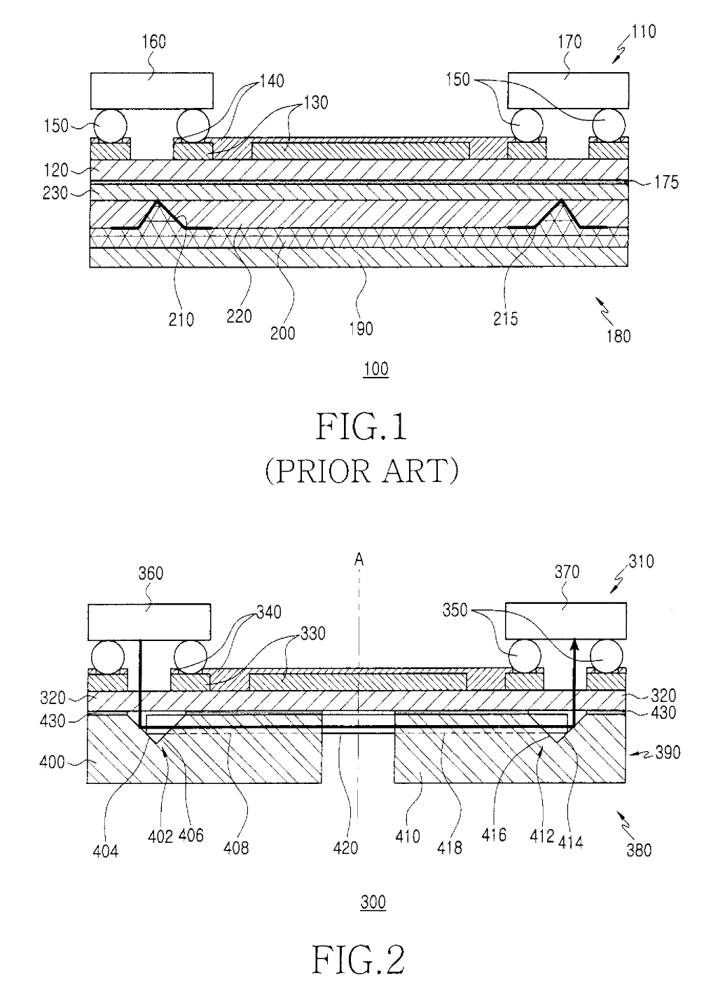

FIG. 2 is a view illustrating a flexible PCB module having a photoelectronic wiring according to an exemplary embodiment of the present invention;

FIG. 3 is a perspective view illustrating the first jig shown in FIG. 2;

FIG. 4 is a plan view illustrating the first jig shown in FIG. 3; and

FIGS. 5 to 11 are sectional views for illustrating a method of manufacturing a flexible PCB module shown in FIG. 2.

### DETAILED DESCRIPTION OF THE INVENTION

Exemplary embodiments of the present invention will be described with reference to the accompanying drawings. Further, in the following description of the present invention, a detailed description of known functions and configurations incorporated herein will be omitted when it may make the subject matter of the present invention unclear.

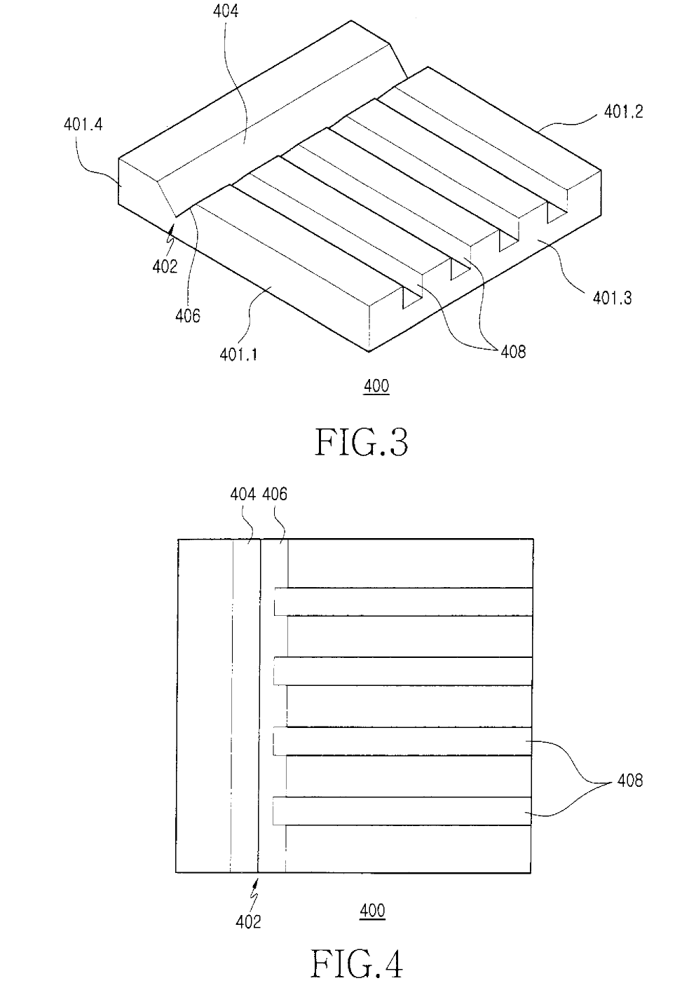

FIG. 2 is a view illustrating a flexible PCB module having a photoelectronic wiring according to an exemplary embodiment of the present invention. The flexible PCB module 300 includes a flexible PCB 310 having at least one light source 360 and at least one optical detector 370 which are mounted on an upper surface thereof, and an optical fiber supporting part 380 attached to a lower surface of the flexible PCB 310 by using adhesives 430. With respect to a reference surface. A dividing the width of the flexible PCB module 300, the light source 360 is positioned at one side of the reference surface A and the optical detector 310 is positioned at the other side of the reference surface A.

The flexible PCB 310 includes a substrate 320, a conductive layer 330, and an upper cover layer 340. The conductive layer 330 is stacked on an upper surface of the substrate 320 and has a pattern for an electric wiring. Such a pattern is formed through a typical photolithography process. The light source 360 and the optical detector 370 are mounted on the conductive layer 330 by using conductive solder balls 350. The light source 360, the optical detector 370, and the conductive layer 330 are electrically connected with each other through the solder balls 350. The light source 360 and the optical detector 370 are driven by the flexible PCB 310. At this time, a light emitting surface of the light source 360 and a light receiving surface of the optical detector 370 face exposed upper surfaces of the substrate 320. The upper cover layer 340 has insulating properties and is stacked on an upper surface of the conductive layer 330 so as to cover an exposed upper surface of the conductive layer 330. A laser diode (LD) may be used as the light source 360, and a photo diode (PD) may be used as the optical detector 370. Polyimide may be used as the material of the substrate 320, copper may be used as the material of the conductive layer 330, and a typical solder resist may be used as the material of the upper cover layer 340.

A plurality of light sources 360 and a plurality of optical detectors 370 corresponding one-to-one to each other may be mounted on the flexible PCB 310.

The optical fiber supporting part 380 includes at least one optical fiber 420, and the first and second jigs 400 and 410 supporting both ends of the optical fiber 420.

The optical fiber 420 has a roughly circular shape, a core of a circular shaped section to be a light transmitting medium, and a clad surrounding the core completely. The core has a refractive index higher than that of the clad, and light is transmitted along the longitudinal direction of the core in the boundary between the core and the clad through total internal reflection. A plastic optical fiber, which has ductility higher than that of an optical fiber of silica material, is preferably used as the optical fiber 420.

The first and second jigs 400 and 410 have the same structure and have the same metal material.

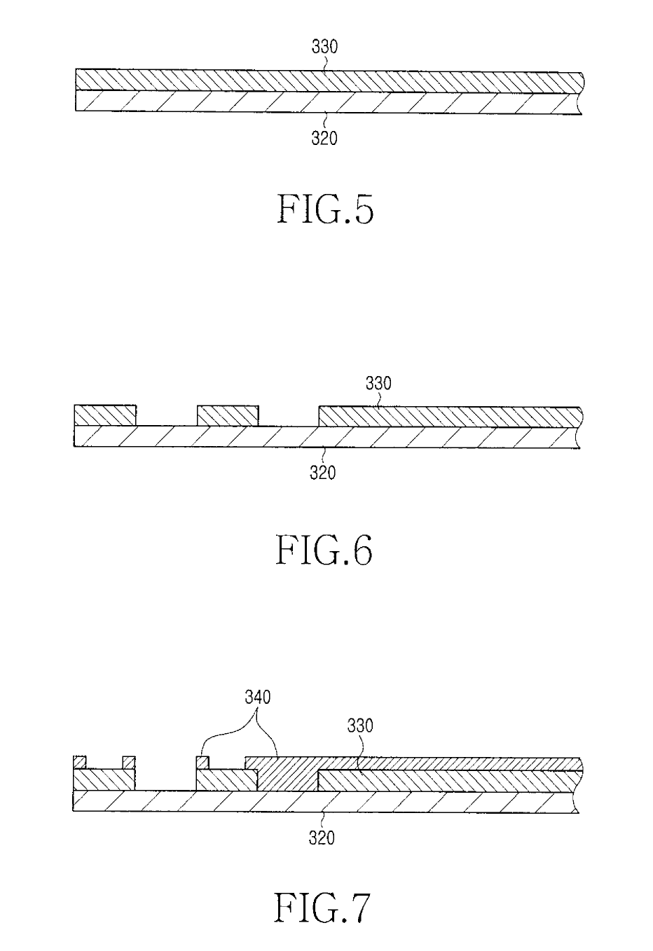

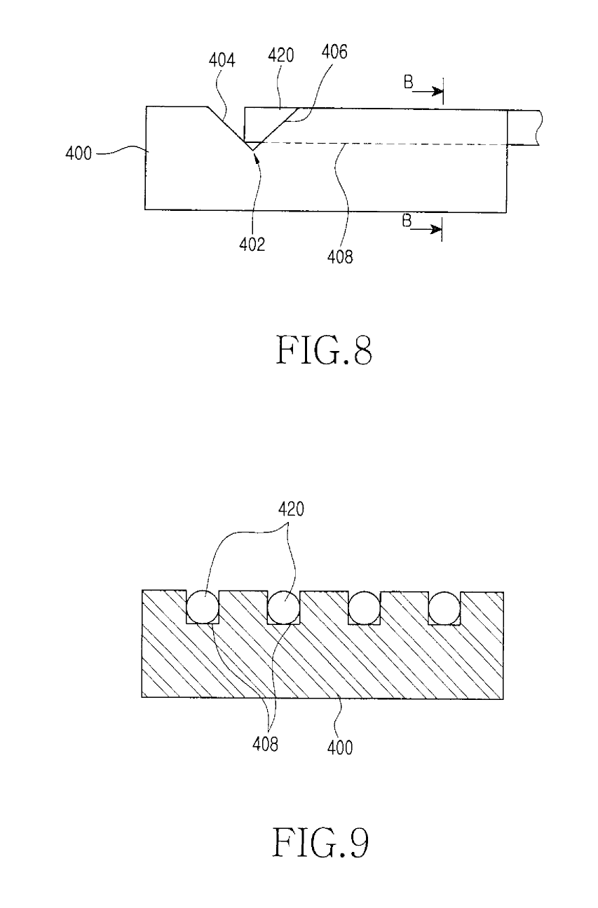

FIG. 3 is a perspective view illustrating the first jig 400, and FIG. 4 is a plan view illustrating the first jig.

The first jig 400 has an approximately rectangular block shape, and has an upper surface, a lower surface, and first to fourth exterior surfaces 401.1-401.4. The first groove 402 and at least one second groove 408 are formed on the upper surface of the first jig 400. At this time, first groove 402 and second groove 408 have a shape of a recess formed from the upper surface of the first jig 400 toward the lower surface thereof, and are spaced from the lower surface of the first jig 400.

The first and second grooves 402 and 408 cross each other while forming a T-shape so as to communicate with each other. The first groove 402 has a V-shaped section and the second groove 408 has a rectangular-shaped section. The first groove 402 extends from the first exterior surface 401.1 of the first jig 400 to the second exterior surface (facing the first exterior surface) 401.2 of the first jig 400. The first groove 402 includes the first and second interior surfaces 404 and 406 which have an interior angle of 90 degrees therebetween. The second groove 408 extends from the third exterior surface 401.3 of the first jig 400 to the second interior surface 406 of the first groove 402. An end of the second groove 408 in a longitudinal direction thereof is exposed to the third exterior surface of the first jig 400. The other end of the second groove 408 in the longitudinal direction thereof is exposed to the second interior surface 406 of the first groove 402. The first interior surface 404 of the first groove 402 functions as a reflecting member respective to the light. Particularly, the first jig 400 has a metallic material, such as aluminum, so that the first interior surface 404 of the first groove 402 can function as a typical metal mirror. Selectively, in order to increase the degree of reflection of the first interior surface 404, the first interior surface 404 can be finely polished or a mirror layer having material such as silver, gold, etc. can be stacked on the first interior surface 404.

The second jig 410 and the first jig 400 have the same structure and material. Particularly, the second jig 410 (referring to FIG. 2) has an approximately rectangular block shape, and has an upper surface, a lower surface, and first to fourth exterior surfaces. The third groove 412 and at least one fourth groove 418 are formed on an upper surface of the second jig 410. The third and forth grooves 412 and 418 intersect each other in a shape like the letter “T” and communicate with each other. The third groove 412 has a V-shaped section and the fourth groove 418 has a rectangular-shaped section. Furthermore, the first interior surface 414 of the third groove 412 functions as a reflecting member with respect to light.

In one aspect, when a mirror layer is stacked on each of the first interior surfaces 404 and 414 and function as a reflecting member, each of the first and second jigs 400 and 410 may have a nonmetallic material such as silicon, etc.

Referring to FIG. 2 again, the first jig 400 supports the first end of the optical fiber 420, the first end of the optical fiber 420 is safely seated in one of the at least one second groove 408. The section (hereinafter, referred to as the first section) of the optical fiber 420, which is included in the first end, faces the first interior surface 404 of the first groove 402. As shown, the first section of the optical fiber 420 is positioned in the first groove 402. At this time, the first section of the optical fiber 420 and the first interior surface 404 of the first groove 402 make a 45 degree angle if they are extended. The first jig 400 is attached to a lower surface of the substrate 320, for example, by adhesives 430. At this time, the first interior surface 404 of the first groove 402 and a light emitting surface of the light source 360 face each other, and if they are extended, make a 45 degree angle therebetween. In other words, the first interior surface 404 of the first groove 402 is arranged along an optical axis (equal to a propagating direction of outputted light) of the light source 360, and is slanted against the optical axis at a 45 degree angle. Adhesives 430 are applied on an upper surface of the first jig 400 and are applied on the residual flat surface, except for the grooves 402 and 408, of the upper surface. At this time, in order to attach the optical fiber 420 to the first jig 400, adhesives can be applied to a part of the optical fiber 420, which is positioned in the second groove 408, or can be applied on a floor surface of the second groove 408.

The second jig 410 supports the second end (i.e., is positioned at the opposite side to the first end) of the optical fiber 420. The optical fiber 420 is seated in the groove 418, and a section (hereinafter, referred to as the second section) of the optical fiber 420, which is included in the second end, faces the first interior surface 414 of the groove 412. As shown, the second section of the optical fiber 420 is positioned in the groove 412. At this time, the second section of the optical fiber 420 and the first interior surface 414 of the groove 412 make a 45 degree angle if they are extended. The second jig 410 is attached to the lower surface of the substrate 320 by using adhesive 430. At this time, the first interior surface 414 of the groove 412 and the light receiving surface of the optical detector 370 face each other, and make a 45 degree angle therebetween. In other words, the first interior surface 414 of the groove 412 is arranged in the optical axis (equal to the reference axis of light receiving angle) of the optical detector 370, and is slanted against the optical axis at 45 degrees. Adhesives 430 are applied on an upper surface of the second jig 410 and are applied on the residual flat surface, except for the grooves 412 and 418, of the upper surface. At this time, in order to attach the optical fiber 420 to the second jig 410, adhesives can be applied to a part of the optical fiber 420 to be positioned in the groove 418, or can be applied on a floor surface of the groove 418.

The light source 360 outputs data-modulated light. Light output from the light source 360 passes through the substrate 320 and enters the first interior surface 404 of the first groove 402. The first interior surface 404 reflects the incident light at a right angle so as to guide the reflected light to the interior of the optical fiber 420 through the first section of the optical fiber 420. At this time, the optical axis of the light source 360 is substantially perpendicular to the longitudinal direction of the optical fiber 420. The light guided to the interior of the optical fiber 420 through the first interior surface 404 of the first groove 402 is transmitted along the longitudinal direction of the optical fiber 420. Particularly, the guided light is transmitted from the first section of the optical fiber 420 to the second section thereof. Light emitted to the exterior of the optical fiber 420 through the second section thereof enters the first interior surface 414 of the groove 412. The first interior surface 414 reflects the incident light at a right angle so that the reflected light can pass through the substrate 320 to enter the light receiving surface of the optical detector 370. At this time, the longitudinal direction of the optical fiber 420 and the optical axis of the optical detector 370 are substantially perpendicular to each other. The optical detector 370 photoelectrically converts input light so as to demodulate data from the input light.

Since the middle part of the optical fiber 420 is not fixed, the flexible PCB module 300 can be bent in a direction of the thickness thereof. In other words, the flexible PCB module 300 can be largely bent, based on the reference surface A). Therefore, the flexible PCB module 300 can have more improved ductility.

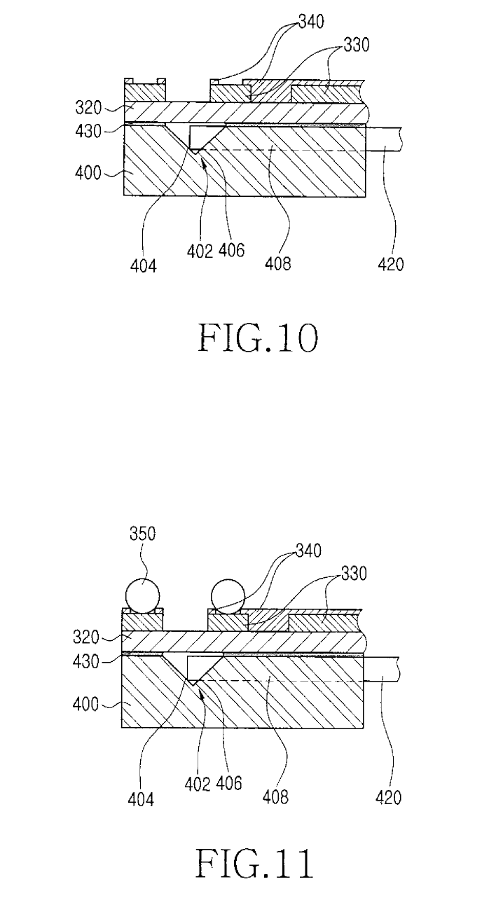

FIGS. 5 to 11 are sectional views for describing a method for manufacturing the flexible PCB module 300. At this time, since respective methods for manufacturing both side parts, based on the reference surface A, are similar to each other, a method for manufacturing the part of the light source 360 will be described hereinafter.

Referring to FIG. 5, a substrate 320 of polyimide material having a conductive layer 330 of copper material stacked on an upper surface thereof is prepared. For example, a copper clad laminate (CCL), which has such a structure and has been commercially used, may be used.

Referring to FIG. 6, a pattern for an electric wiring is formed on the conductive layer 330 through a typical photolithography process. For example, a photoresistant layer is stacked on the conductive layer 330, the photoresistant layer is exposed through irradiation of ultraviolet light passing through a mask, the photoresistant layer is developed, the conductive layer 300 is etched by using the developed photoresistant layer, and the residual photoresistant layer is removed by using removal liquid.

Referring to FIG. 7, in order to cover an upper surface, except for a part on which solder balls will be disposed, of the conductive layer 330, an upper cover layer 340 is stacked on an upper surface of the conductive layer 330. A typical solder resist may be used as the upper cover layer 340. For example, a solder resist is stacked on the conductive layer 330 by screen printing, the solder resist is pre-cured, the photoresistant layer is exposed through irradiation of ultraviolet light passing through a mask, and the solder resist is developed and post-cured.

Referring to FIGS. 8 and 9, the first jig 400 having the first groove 402 and at least one second groove 408 is prepared. The first end of an optical fiber 420 is disposed in the second groove 408 (FIG. 9). At this time, the first section of the optical fiber 420 is positioned in the first groove 402. At this time, the first section of the optical fiber 420 and the first interior surface 404 of the first groove 402 are arranged to make a 45 degree angle if they are extended (FIG. 8).

Referring to FIG. 10 an upper surface of the first jig 400 is attached to the lower surface of the substrate 320 by using adhesives 430.

Referring to FIG. 11, the solder balls 350 are arranged on the upper surface of the conductive layer 330.

The light source 360 and the optical detector 370 are mounted on the solder balls 350. Therefore, the flexible PCB module 300 as shown in FIG. 2 can be obtained.

As described above, the flexible PCB module having a photoelectronic wiring according to present invention uses an optical fiber for an optical wiring, and has such a structure that both ends of the optical fiber are fixed by using a supporting part, and the middle part of the optical fiber is not fixed. Therefore, there is an advantage in having a more improved ductility.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A flexible printed circuit board module comprising:
a flexible printed circuit board having a conductive layer in an upper part of the flexible printed circuit board;
an optical fiber disposed under the flexible printed circuit board, wherein light propagates through an interior of the optical fiber; and
a supporting member supporting the optical fiber and having a first reflecting member reflecting incident light from the flexible printed circuit board so as to guide the light to the optical fiber.

2. The flexible printed circuit board module as claimed in claim 1, further comprising:
a light source outputting data-modulated light, the light source being mounted on the conductive layer; and
a optical detector photoelectrically converting inputted light, the optical detector being mounted on the conductive layer,
wherein the supporting member further comprises a second reflecting member reflecting light propagating through an interior of the supporting member to the optical detector.

3. The flexible printed circuit board module as claimed in claim 2, wherein the supporting member comprises:
a first jig supporting a first end of the optical fiber, having the first reflecting member, and being fixed to a lower surface of the flexible printed circuit board; and
a second jig supporting a second end of the optical fiber, having the second reflecting member and being fixed to the lower surface of the flexible printed circuit board.

4. The flexible printed circuit board module as claimed in claim 3, wherein each of the jigs comprises a first groove providing a corresponding reflecting member, and a second groove crossing the first groove so as to communicate each other.

5. The flexible printed circuit board module as claimed in claim 4, wherein the reflecting member is one surface constituting the first groove.

6. The flexible printed circuit board module as claimed in claim 2, wherein each of the reflecting members is slanted against the longitudinal direction of the optical fiber substantially at a 45 degree angle.

7. The flexible printed circuit board module as claimed in claim 2, wherein each of the reflecting members includes a mirror surface.

8. The flexible printed circuit board module as claimed in claim 7, wherein said mirror surface is made of a highly reflective material.

9. The flexible printed circuit board module as claimed in claim 5, wherein said first groove comprises:
said reflecting surface; and
an angled surface, having substantially a 90 degree angle therebetween.

10. The flexible printed circuit board module as claimed in claim 1, wherein said support member is composed of a material selected from the group consisting of: metallic and non-metallic.

11. A method for fabricating a flexible PCB supporting member comprising:
cutting a first groove from a first end to a second end of said supporting member, said first groove having a first surface extend substantially at a 45 degree angle along said direction of said first groove; and
cutting at least one second groove substantially perpendicular to said first groove, each of said at least one second groove extending from said first groove to a third end of said support member, wherein said first surface extends away from said third surface.

12. The method as claimed in claim 11, further comprising:
forming a mirror surface on said first surface.

13. The method as claimed in claim 12, wherein said mirror surface is formed by depositing a highly reflective material on said first surface.

14. The method as claimed in claim 12, wherein said mirror surface is formed by polishing said first surface.

15. The method as claimed in claim 11, wherein said first groove further comprises a second surface extending substantially at a 45 degree angle along said direction of said first groove, wherein said first and second surfaces form an angle of substantially 90 degrees therebetween.

16. A flexible PCB assembly comprising:
a light source and a light detector formed on a first surface of a conductive plate, said conductive plate having openings therein to allow light to pass therethrough;
a supporting assembly comprising first and second jig members attached to a second surface of a conductive plate, said supporting assembly comprising:
a first joining assembly and a second joining assembly, each including a first groove traversing said assembly and at least one second groove extending substantially perpendicular from said first groove, said first groove having at least one surface extending at substantially a 45 degree angle in the direction of said first groove, wherein said first joining assembly is position to receive a light from said light source and said second joining assembly is positioned to provide a light to said light detector; and
an optical fiber positioned in respective ones of said at least one second groove and extending between said first joining assembly and said second joining assembly, wherein light from said light source is directed toward one end of said optical fiber via said 45 degree angle surface in said first joining assembly and light exiting a second end of said optical fiber is directed toward said light detector via said 45 degree angle surface in said second joining assembly.

17. The assembly as claimed in claim 16, wherein at least one of said 45 degree angle surfaces includes a mirror surface.

18. The assembly as claimed in claim 17, wherein said mirror surface is formed by depositing a highly reflective material on said 45 degree angle surface.

19. The assembly as claimed in claim 17, wherein said mirrored surface is formed by polishing said 45 degree angle surface.

20. The assembly as claimed in claim 16, wherein each of said first and second joining assemblies is composed of a material selected from the group consisting of: metallic and non-metallic.
